(19) United States
(12) Patent Application Publication
(10) Pub. No.: US 2012/0077002 A1
(43) Pub. Date: Mar. 29, 2012

(54) COATED ARTICLE AND METHOD FOR MAKING THE SAME

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); CONG LI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/150,366

(22) Filed: Jun. 1, 2011

(30) Foreign Application Priority Data
Sep. 29, 2010 (CN) 201010296611.7

(51) Int. Cl. B32B 27/06; C23C 14/34; B32B 15/085; B32B 7/02

(52) U.S. Cl. 428/213; 428/422; 204/192.15

(57) ABSTRACT

A coated article is provided. The coated article includes a substrate, a first anti-fingerprint layer formed on the substrate, and a second anti-fingerprint layer formed on the first anti-fingerprint layer. The first anti-fingerprint layer is a polytetrafluoroethylene layer. The second anti-fingerprint layer is a compound layer of polytetrafluoroethylene and aluminum-oxygen-nitrogen. A method for making the coated article is also described therein.

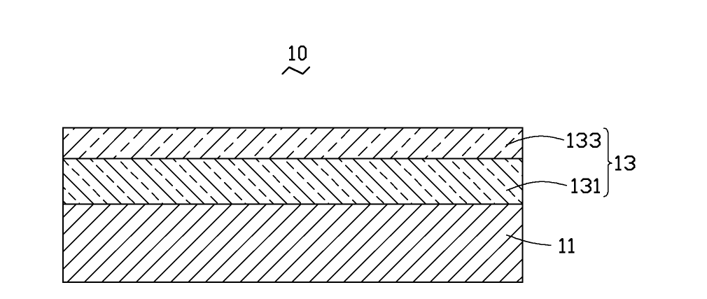

### CROSS-REFERENCE TO RELATED APPLICATIONS

This application is one of the three related co-pending U.S. patent applications listed below. All listed applications have the same assignee. The disclosure of each of the listed applications is incorporated by reference into all the other listed applications.

| Attorney | | |
|---|---|---|
| Docket No. | Title | Inventors |
| US 34428 | DEVICE HOUSING AND METHOD | HSIN-PEI CHANG |
| | FOR MAKING THE SAME | et al. |
| US 34432 | COATED ARTICLE AND METHOD | HSIN-PEI CHANG |
| | FOR MAKING THE SAME | et al. |
| US 34433 | COATED ARTICLE AND METHOD | HSIN-PEI CHANG |
| | FOR MAKING THE SAME | et al. |

### BACKGROUND

1. Technical Field

The present disclosure relates to coated articles, particularly to a coated article having an anti-fingerprint property and a method for making the coated article.

2. Description of Related Art

Many electronic coated articles are coated with anti-fingerprint film. These anti-fingerprint films are commonly painted with a paint containing organic anti-fingerprint substances. However, the print films are thick (commonly 2 μm-4 μm) and not very effective. Furthermore, the paint may not be environmentally friendly.

Therefore, there is room for improvement within the art.

### BRIEF DESCRIPTION OF THE FIGURE

Many aspects of the coated article can be better understood with reference to the following FIGURE. The components in the FIGURE are not necessarily drawn to scale, the emphasis instead being placed upon clearly illustrating the principles of the coated article.

The FIGURE is a cross-sectional view of an exemplary embodiment of a coated article.

### DETAILED DESCRIPTION

The FIGURE shows a coated article 10 according to an exemplary embodiment. The coated article 10 includes a substrate 11, and an anti-fingerprint layer 13 formed on a surface of the substrate 11. The anti-fingerprint layer 13 includes a first anti-fingerprint layer 131 and a second anti-fingerprint layer 133.

The substrate 11 may be made of metal or plastic material.

The first anti-fingerprint layer 131 may be a polytetrafluoroethylene (PTFE) layer. The first anti-fingerprint layer 131 is formed on the substrate 11 by an environmentally friendly vacuum sputtering deposition.

The second anti-fingerprint layer 133 may be a compound layer of polytetrafluoroethylene (PTFE) and aluminum-oxygen-nitrogen (Al—O—N). The second anti-fingerprint layer 133 is formed on the first anti-fingerprint layer 131 by an environmentally friendly vacuum sputtering deposition. The Al—O—N within the second anti-fingerprint layer 133 makes the second anti-fingerprint layer 133 be of a high rigidity and a good abrasion resistance.

The total thickness of the first anti-fingerprint layer 131 and the second anti-fingerprint layer 133 may be less than 1 μm, and in the exemplary embodiment may be 0.1 μm-0.5 μm. The first and the second anti-fingerprint layers are transparent and glossy. The anti-fingerprint layer 13 has a good anti-fingerprint property.

A method for making the coated article 10 may include the following steps:

The substrate 11 is pretreated. The pre-treating process may include the following steps:

The substrate 11 is cleaned in an ultrasonic cleaning device (not shown) filled with ethanol or acetone.

The substrate 11 is plasma cleaned. The substrate 11 may be positioned in a plating chamber of a vacuum sputtering equipment (not shown). The plating chamber is fixed with a polytetrafluoroethylene (PTFE) target and an aluminum target therein. The plating chamber is then evacuated to about 4.0×10⁻³ Pa. Argon (Ar, having a purity of about 99.999%) may be used as a working gas and is injected into the chamber at a flow rate of about 300 standard-state cubic centimeters per minute (sccm) to 500 sccm. The substrate 11 may have a negative bias voltage at a range of −300V-−500 V, and so high-frequency voltage is produced in the plating chamber and the Ar is ionized to plasma. The plasma then strikes the surface of the substrate 11 to clean the surface of the substrate 11. Plasma cleaning the substrate 11 may take about 3 minutes (min) to 10 min. The plasma cleaning process enhances the bond between the substrate 11 and the anti-fingerprint layer 13. The targets there are unaffected by the plasma cleaning process.

The first anti-fingerprint layer 131 is vacuum sputtered on the pretreated substrate 11. Vacuum sputtering of the anti-fingerprint layer 131 is implemented in the plating chamber of the vacuum sputtering equipment. The inside of the plating chamber is heated to about 20° C.-300° C. Argon (Ar) may be used as a working gas and is injected into the chamber at a flow rate of about 5 sccm -150 sccm. Nitrogen (N₂) and acetylene (C₂H₂) may be used as reaction gases and are injected into the chamber. The flow rate of the N₂ may be 5 sccm-70 sccm, and the flow rate of the C₂H₂ may be 5 sccm-60 sccm. Power is applied to the polytetrafluoroethylene target fixed in the plating chamber, and the substrate 11 may be have a negative bias voltage of about −100 V-−300 V to deposit the first anti-fingerprint layer 131 on the substrate 11. Depositing of the first anti-fingerprint layer 131 may take about 20 min-60 min.

The second anti-fingerprint layer 133 is formed on the first anti-fingerprint layer 131 by vacuum sputtering. Vacuum sputtering of the second anti-fingerprint layer 133 is implemented in the plating chamber of the vacuum sputtering equipment. The internal temperature of the plating chamber is maintained at about 20° C.-300° C. Argon (Ar) may be used as a working gas and is injected into the chamber at a flow rate of about 5 sccm-150 sccm. Nitrogen (N₂) and oxygen (O₂) may be used as reaction gases and are injected into the chamber at a flow rate of about 5 sccm-70 sccm and 10 sccm-60 sccm respectively. Power is applied to the polytetrafluoroethylene target and the aluminum target fixed in the plating chamber simultaneously. The substrate 11 may have a negative bias voltage to deposit the second anti-fingerprint layer 133 on the first anti-fingerprint layer 131. Depositing of the second anti-fingerprint layer 133 may take about 20 min-60 min.

A glow discharge atomic emission spectrometry (GD-OES) test has been implemented to the coated article 10. The test indicates that the Al, O, and N elements of the second anti-fingerprint layer 133 are evenly distributed in the second anti-fingerprint layer 133.

The anti-fingerprint property of the anti-fingerprint layer 13 has been tested by using a dyne test pen (brand: ACCU; the place of production: U.S.A.). The test indicates that the surface tension of the anti-fingerprint layer 13 is below 30 dynes, thus, the anti-fingerprint layer 13 has a good anti-fingerprint property.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A coated article, comprising:
a substrate;
a first anti-fingerprint layer formed on the substrate, the first anti-fingerprint layer being a polytetrafluoroethylene layer; and
a second anti-fingerprint layer formed on the first anti-fingerprint layer, the second anti-fingerprint layer being a compound layer of polytetrafluoroethylene and aluminum-oxygen-nitrogen.

2. The coated article as claimed in claim 1, wherein the first anti-fingerprint layer and the second anti-fingerprint layer have a total thickness of less than 1 μm.

3. The coated article as claimed in claim 2, wherein the first anti-fingerprint layer and the second anti-fingerprint layer have a total thickness of about 0.1 μm-0.5 μm.

4. The coated article as claimed in claim 1, wherein the first anti-fingerprint layer and the second anti-fingerprint layer are formed by vacuum sputtering.

5. The coated article as claimed in claim 1, wherein the substrate is made of metal or plastic material.

6. A method for making a coated article, comprising:
providing a substrate;
forming a first anti-fingerprint layer on the substrate by vacuum sputtering, the first anti-fingerprint layer being a polytetrafluoroethylene layer; and
forming a second anti-fingerprint layer on the first anti-fingerprint layer by vacuum sputtering, the second anti-fingerprint layer being a compound layer of polytetrafluoroethylene and aluminum-oxygen-nitrogen.

7. The method as claimed in claim 6, wherein vacuum sputtering the first anti-fingerprint layer uses a polytetrafluoroethylene target; uses nitrogen and acetylene as reaction gases, the nitrogen has a flow rate of about 5 sccm-70 sccm, the acetylene has a flow rate of about 5 sccm-60 sccm; uses argon as a working gas, the argon has a flow rate of about 5 sccm-150 sccm; vacuum sputtering the first anti-fingerprint layer is at a temperature of about 20° C.-300° C.; vacuum sputtering the first anti-fingerprint layer takes about 20 min-60 min.

8. The method as claimed in claim 7, wherein the substrate is biased with a negative bias voltage of about −100V-−300V during vacuum sputtering the first anti-fingerprint layer.

9. The method as claimed in claim 6, wherein vacuum sputtering the second anti-fingerprint layer uses polytetrafluoroethylene target and aluminum target; uses nitrogen and oxygen as reaction gases, the nitrogen has a flow rate of about 5 sccm-70 sccm, the oxygen has a flow rate of about 10 sccm-60 sccm; uses argon as a working gas, the argon has a flow rate of about 5 sccm-150 sccm; vacuum sputtering the second anti-fingerprint layer is at a temperature of about 20° C.-300° C.; vacuum sputtering the second anti-fingerprint layer takes about 20 min-60 min.

10. The method as claimed in claim 9, wherein the substrate is biased with a negative bias voltage of about −100V-−300V during vacuum sputtering the second anti-fingerprint layer.

11. The method as claimed in claim 6, further comprising a step of pre-treating the substrate before forming the first anti-fingerprint layer.

12. The method as claimed in claim 11, wherein the pre-treating process comprising ultrasonic cleaning the substrate and plasma cleaning the substrate.

13. The method as claimed in claim 12, wherein plasma cleaning the substrate uses argon as a working gas, the argon has a flow rate of about 300 sccm-500 sccm; the substrate is biased with negative bias voltage at a range of −300V-−500 V; plasma cleaning of the substrate takes about 3 min-10 min.

14. The method as claimed in claim 6, wherein the substrate is made of metal material or plastic material.
